(19) United States
(12) Patent Application Publication
(10) Pub. No.: US 2025/0294990 A1
(43) Pub. Date: Sep. 18, 2025

(54) DISPLAY PANEL AND DISPLAY APPARATUS

(71) Applicant: Xiamen Tianma Micro-Electronics Co., Ltd., Xiamen (CN)

(72) Inventor: Liting FANG, Xiamen (CN)

(21) Appl. No.: 18/734,070

(22) Filed: Jun. 5, 2024

(30) Foreign Application Priority Data
Mar. 14, 2024 (CN) 202410294586.0

(51) Int. Cl. H10K 59/35; G02B 27/01

(52) U.S. Cl. CPC H10K 59/353; G02B 27/0101; H10K 59/352

(57) ABSTRACT

A display panel includes a plurality of pixels. A pixel of the plurality of pixels includes a plurality of color sub-pixels. One color sub-pixel of the plurality of color sub-pixels of the pixel is a primary color sub-pixel, and other color sub-pixels are auxiliary color sub-pixels. When the primary color sub-pixel of the pixel is turned on, the auxiliary color sub-pixels of the pixel are turned on. The auxiliary color sub-pixels of the pixel and partial light of the primary color sub-pixel are mixed into white light and the pixel displays a primary color.

### CROSS-REFERENCE TO RELATED APPLICATION

This application claims priority to Chinese Patent Application No. 202410294586.0, filed on Mar. 14, 2024, the entire content of which is incorporated herein by reference.

### TECHNICAL FIELD

The present disclosure relates to the field of display technology and, in particular, to a display panel, a driving method thereof, and a display apparatus.

### BACKGROUND

Head-Up Display (HUD) is a technology that utilizes the principle of optical reflection to project important driving-related information onto the windshield. The content that automotive HUD needs to display has transitioned from conventional simple displays to those based on Augmented Reality (AR) displays. Therefore, there is an increasing demand for improvements in display quality and National Television System Committee (NTSC) color gamut saturation. The NTSC color gamut refers to the sum of colors under the NTSC standard. Additionally, one of the key performance factors of HUD is readability in sunlight. In bright ambient light conditions, enhancing brightness and contrast are crucial for the user experience of automotive HUD. HUD products fail to achieve a high display brightness while ensuring the necessary NTSC color gamut saturation.

HUD products typically use Liquid Crystal Display (LCD) technology. To ensure a necessary NTSC color gamut saturation, it is normally to increase the thickness of the Color Filter (CF) film. However, increasing the thickness of the CF film layer decreases its transmittance. Therefore, to improve transmittance, it is necessary to make the CF film layer as thin as possible. Consequently, HUD products struggle to achieve a high display brightness while ensuring the necessary NTSC color gamut saturation.

### SUMMARY

One aspect of the present disclosure provides a display panel. The display panel includes a plurality of pixels. A pixel of the plurality of pixels has a plurality of color sub-pixels. One color sub-pixel of the plurality of color sub-pixels of the pixel is a primary color sub-pixel, and other color sub-pixels are auxiliary color sub-pixels. When the primary color sub-pixel of the pixel is turned on, the auxiliary color sub-pixels of the pixel are turned on. Auxiliary color sub-pixels of the pixel and partial light of the primary color sub-pixel are mixed into white light. The pixel displays a primary color.

One aspect of the present disclosure provides a display apparatus. The display apparatus includes a display panel. The display panel includes a plurality of pixels. A pixel of the plurality of pixels has a plurality of color sub-pixels. One color sub-pixel of the plurality of color sub-pixels of the pixel is a primary color sub-pixel, and other color sub-pixels are auxiliary color sub-pixels. When the primary color sub-pixel of the pixel is turned on, the auxiliary color sub-pixels of the pixel are turned on. Auxiliary color sub-pixel of the pixels and partial light of the primary color sub-pixel are mixed into white light. The pixel displays a primary color.

### BRIEF DESCRIPTION OF THE DRAWINGS

The drawings included herein are incorporated into and form part of this specification, illustrating embodiments consistent with the present disclosure and, together with the specification, serve to explain the principles of the present disclosure.

To further clarify the technical solutions in embodiments of the present disclosure, brief introductions to the drawings required for the embodiments will be provided below. It is evident that those persons of ordinary skill in the art can obtain additional drawings based on these drawings without exercising inventive effort.

FIG. 1 illustrates a schematic diagram of a pixel arrangement of a display panel according to embodiments of the present disclosure.

FIG. 2 illustrates a schematic diagram of another pixel arrangement of a display panel according to embodiments of the present disclosure.

FIG. 3 illustrates a schematic diagram of another pixel arrangement of a display panel according to embodiments of the present disclosure.

FIG. 4 illustrates a schematic diagram of another pixel arrangement of a display panel according to embodiments of the present disclosure.

FIG. 5 illustrates a schematic diagram of a cross-sectional structure of a display panel according to embodiments of the present disclosure.

FIG. 6 illustrates a schematic diagram of another cross-sectional structure of a display panel according to embodiments of the present disclosure.

FIG. 7 illustrates a schematic diagram of another cross-sectional structure of a display panel according to embodiments of the present disclosure.

FIG. 8 illustrates a schematic diagram of another pixel arrangement of a display panel according to embodiments of the present disclosure.

FIG. 9 illustrates a schematic diagram of another pixel arrangement of a display panel according to embodiments of the present disclosure.

FIG. 10 illustrates a schematic diagram of another pixel arrangement of a display panel according to embodiments of the present disclosure.

FIG. 11 illustrates a schematic diagram of another pixel arrangement of a display panel according to embodiments of the present disclosure.

FIG. 12 illustrates a schematic diagram of another pixel arrangement of a display panel according to embodiments of the present disclosure.

FIG. 13 illustrates a schematic diagram of another pixel arrangement of a display panel according to embodiments of the present disclosure.

FIG. 14 illustrates a schematic diagram of another pixel arrangement of a display panel according to embodiments of the present disclosure.

FIG. 15 illustrates a schematic diagram of another pixel arrangement of a display panel according to embodiments of the present disclosure.

FIG. 16 illustrates a schematic diagram of another pixel arrangement of a display panel according to embodiments of the present disclosure.

FIG. 17 illustrates a schematic diagram of another pixel arrangement of a display panel according to embodiments of the present disclosure.

FIG. 18 illustrates a schematic diagram of another pixel arrangement of a display panel according to embodiments of the present disclosure.

FIG. 19 illustrates a schematic diagram of another pixel arrangement of a display panel according to embodiments of the present disclosure.

FIG. 20 illustrates a schematic diagram of a display apparatus according to embodiments of the present disclosure.

FIG. 21 illustrates a flowchart of a driving method for a display panel according to embodiments of the present disclosure.

### DETAILED DESCRIPTION OF THE EMBODIMENTS

In order to better convey the above objectives, features, and advantages of the present disclosure, embodiments of the present disclosure will be further described below. It should be noted that, unless conflicting, embodiments and features described herein can be combined with each other.

The description below provides many specific details to enable a comprehensive understanding of the present disclosure. However, the present disclosure can be implemented in other ways not described herein. Embodiments described in this specification are only part of the embodiments of the present disclosure, not all of them.

The present disclosure addresses the challenges in Head-Up Display (HUD), which utilizes Liquid Crystal Display (LCD) for display. In order to ensure a necessary NTSC color gamut saturation, a Color Filter (CF) film thickness needs to be increased, but this results in a decrease in the transmittance of the thickened CF film layer. Therefore, in order to improve transmittance, it is necessary to minimize the thickness of the CF film. Consequently, there is a pressing need for a display panel that can ensure the necessary NTSC color gamut saturation while achieving a high display brightness.

To address the above issues, embodiments of the present disclosure provide a display panel having a plurality of pixels. Each pixel includes a plurality of color sub-pixels. One color sub-pixel of the plurality of color sub-pixels of the pixel is a primary color sub-pixel, and other color sub-pixels are auxiliary color sub-pixels. When the primary color sub-pixel of the pixel is turned on, the auxiliary color sub-pixels of the pixel are also turned on to mix with partial light of the primary color sub-pixel to produce white light, and the pixel presents the primary color. This ensures that the HUD technology meets the requirements of NTSC color gamut saturation. Additionally, by synchronously turning on the auxiliary color sub-pixels with the primary color sub-pixel, light of the auxiliary color sub-pixels and partial light of the primary color sub-pixel are mixed to be a white light. The white light is used to increase the brightness of the pixel, thereby increasing the brightness of the display panel. This enables the display panel to meet the brightness requirements of HUD technology and improves the display effect of the display panel.

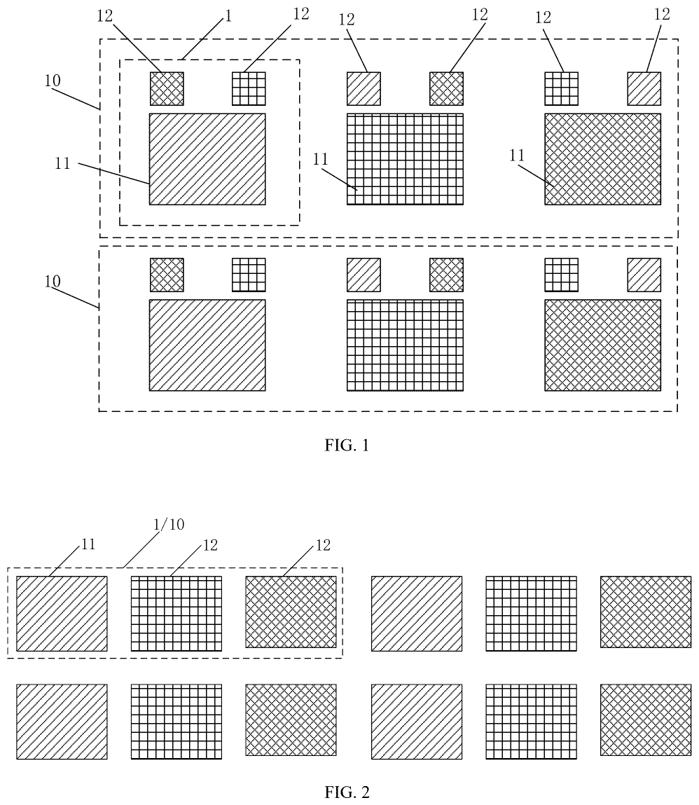

FIG. 1 illustrates a schematic diagram of a pixel arrangement of a display panel according to embodiments of the present disclosure. As shown in FIG. 1, six pixels 1 are exemplarily illustrated. Each pixel 1 has one primary color sub-pixel 11 and two auxiliary color sub-pixels 12 of different colors. The two auxiliary color sub-pixels 12 are located in a different row than the primary color sub-pixel 11. When the primary color sub-pixel 11 of the pixel 1 is turned on, the auxiliary color sub-pixels 12 of the pixel 1 are also turned on. Light of the auxiliary color sub-pixels 12 of the pixel 1 mixes with partial light of the primary color sub-pixel 11 of the pixel 1 to produce white light, and the pixel 1 presents the primary color.

FIG. 2 illustrates a schematic diagram of another pixel arrangement of a display panel provided in embodiments of the present disclosure. As shown in FIG. 2, four pixels 1 are exemplarily illustrated. The primary color sub-pixel 11 and the auxiliary color sub-pixels 12 are located in a same row. FIG. 2 takes an example of the pixel 1 displaying red. A red sub-pixel is set as the primary color sub-pixel 11. A green sub-pixel and a blue sub-pixel are set as auxiliary color sub-pixels 12. It can be understood that when the pixel 1 needs to display green, the green sub-pixel is set as the primary color sub-pixel 11, and the red sub-pixel and the blue sub-pixel are set as the auxiliary color sub-pixels 12. When the pixel 1 needs to display blue, the blue sub-pixel is set as the primary color sub-pixel 11. The red sub-pixel and the green sub-pixel are set as the auxiliary color sub-pixels 12. Different filling patterns are used to distinguish between the red, green, and blue sub-pixels in FIG. 1 and FIG. 2. Further explanation regarding the presentation of pixel 1 in different colors is provided below.

Exemplarily, when pixel 1 needs to display red, the primary color sub-pixel 11 is set to be the red sub-pixel, and the auxiliary color sub-pixels 12 are set to be the green sub-pixel and the blue sub-pixel. When the red sub-pixel is turned on, the green sub-pixel and the blue sub-pixel are also turned on. The green light emitted by the green sub-pixel, the blue light emitted by the blue sub-pixel, and partial red light emitted by the red sub-pixel are mixed to produce white light. Consequently, this can enhance the brightness of the display panel. After emitting the remaining part of the red light by the red sub-pixel, pixel 1 displays red.

When pixel 1 needs to display green, the primary color sub-pixel 11 is set to be the green sub-pixel, the red sub-pixel and the blue sub-pixel are set as the auxiliary color sub-pixels 12. When the green sub-pixel is turned on, the red sub-pixel and the blue sub-pixel are also turned on. The red light emitted by the red sub-pixel, the blue light emitted by the blue sub-pixel, and partial green light emitted by the green sub-pixel are mixed to produce white light. Consequently, this can enhance the brightness of the display panel. After emitting the remaining part of the green light by the green sub-pixel, pixel 1 displays green.

When pixel 1 needs to display blue, the primary color sub-pixel 11 is set to be the blue sub-pixel, the red sub-pixel and the green sub-pixel are set as the auxiliary color sub-pixels 12. When the blue sub-pixel is turned on, the red sub-pixel and the green sub-pixel are also turned on. The red light emitted by the red sub-pixel, the green light emitted by the green sub-pixel, and partial blue light emitted by the blue sub-pixel are mixed to produce white light. Consequently, this can enhance the brightness of the display panel. After emitting the remaining part of the blue light by the blue sub-pixel, pixel 1 displays blue.

In some embodiments, by setting one sub-pixel of a plurality of color sub-pixels of a pixel as the primary color sub-pixel 11 and other sub-pixels as the auxiliary color sub-pixels 12, the pixel 1 still displays the primary color. This ensures that the HUD technology meets the requirements of NTSC color gamut saturation. Additionally, by synchronously turning on the auxiliary color sub-pixels 12 with the primary color sub-pixel 11, light from the auxiliary color sub-pixels 12 and partial light from the primary color sub-pixel 11 are mixed to produce white light. Utilizing white light to enhance the brightness of pixel 1, thereby increasing the brightness of the display panel. This makes the display panel meet the brightness requirements of HUD technology and improves the display effect of the display panel.

Optionally, as shown in FIG. 1, the display panel has a plurality of pixel units 10. Each pixel unit 10 has a plurality of pixels 1. Colors of primary color sub-pixels 11 in a same pixel unit 10 are different.

Specifically, FIG. 1 exemplarily illustrates two pixel units 10 in the display panel. Each pixel unit has three pixels 1, and each pixel 1 has a primary color sub-pixel 11 and two auxiliary color sub-pixels 12. The three primary color sub-pixels 11 in a same pixel unit 10, for instance, are respectively red sub-pixel, green sub-pixel, and blue sub-pixel, achieving color display in the display panel.

FIG. 1 exemplarily illustrates the arrangement of primary color sub-pixels 11 of three pixels 1 in one pixel unit 10 is in a sequence of red sub-pixel, green sub-pixel, and blue sub-pixel. The primary color sub-pixels 11 in a same column of pixel 1 have a same color. It should be noted that the pixel 1 of the display panel can also be arranged in other ways to meet the display requirements. Embodiments of the present disclosure do not limit the arrangement.

Optionally, as shown in FIG. 1, an area of the primary color sub-pixel 11 is greater than that of the auxiliary color sub-pixels 12.

Exemplarily, as shown in FIG. 1, when the primary color sub-pixel 11 is the red sub-pixel, and the auxiliary color sub-pixels 12 are the green sub-pixel and the blue sub-pixel, the area of the red sub-pixel is greater than that of the green sub-pixel. The area of the red sub-pixel is also greater than that of the blue sub-pixel. Similarly, when the primary color sub-pixel 11 is the green sub-pixel, and the auxiliary color sub-pixels 12 are the red sub-pixel and the blue sub-pixel, the area of the green sub-pixel is greater than that of the red sub-pixel. The area of the green sub-pixel is also greater than that of the blue sub-pixel. Likewise, when the primary color sub-pixel 11 is the blue sub-pixel, and the auxiliary color sub-pixels 12 are the red sub-pixel and the green sub-pixel, the area of the blue sub-pixel is greater than that of the red sub-pixel. The area of the blue sub-pixel is also greater than that of the green sub-pixel.

It should be noted that the areas of the two auxiliary color sub-pixels 12 in the same pixel unit 10 can be equal or unequal. Embodiments of the present disclosure does not limit it.

Therefore, by setting the area of the primary color sub-pixel 11 to be greater than that of the auxiliary color sub-pixels 12, it avoids the auxiliary color sub-pixels 12 excessively occupying of the area of the primary color sub-pixel 11. This also prevents a decrease in saturation when the display panel displays the primary color, which would fail to meet the display requirements. Additionally, if the area of the auxiliary color sub-pixels is too large, it will also affect the brightness of the primary color sub-pixel, causing deviations in display chromaticity. Therefore, the areas of the primary color sub-pixel and the auxiliary color sub-pixels can be set according to the actual requirements of display effect. On the premise of increasing the brightness of the primary color sub-pixel 11, although the saturation of the primary color sub-pixel decreases, caused by mixing the partial light of the primary color sub-pixel with the light of the auxiliary color sub-pixels, the area of the primary color sub-pixel 11 is greater than that of the auxiliary color sub-pixels 12. The saturation of the primary color sub-pixel 11 still meets the saturation requirements of the primary color in the display.

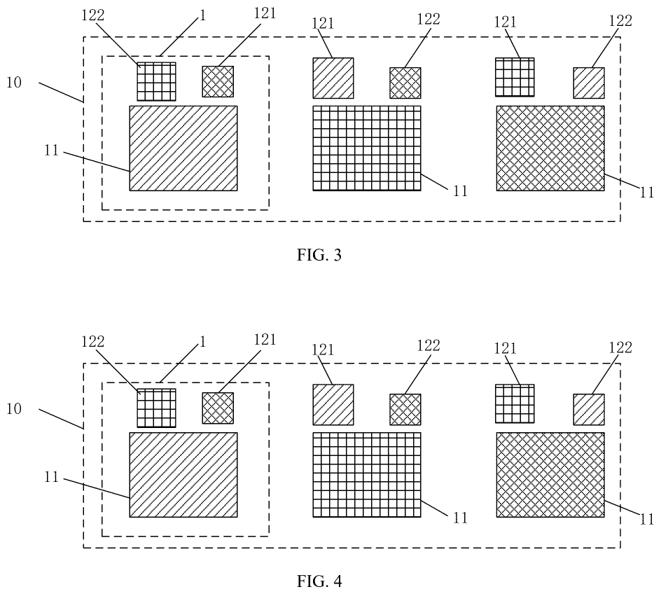

FIG. 3 illustrates a schematic diagram of another pixel arrangement of a display panel according to embodiments of the present disclosure. Optionally, as shown in FIG. 3, the auxiliary color sub-pixels 12 in pixel 1 includes at least a first auxiliary color sub-pixel 121 and a second auxiliary color sub-pixel 122. An area of the first auxiliary color sub-pixel 121 is greater than an area of the second auxiliary color sub-pixel 122. Human eye sensitivity to the first auxiliary color sub-pixel 121 is greater than the human eye sensitivity to the second auxiliary color sub-pixel 122.

Specifically, as shown in FIG. 3, when it is necessary to increase the brightness of the display panel, enlarging the area of the auxiliary color sub-pixel 12 can enhance the brightness of the auxiliary color sub-pixel 12, thereby increasing the brightness of pixel 1 and the overall brightness of the display panel. Since the human eye sensitivity to the first auxiliary color sub-pixel 121 is higher, it contributes more to the brightness of the display panel. A large area of the first auxiliary color sub-pixel 121 leads to a significant effect on increasing the brightness of the display panel. Therefore, setting the area of the first auxiliary color sub-pixel 121 larger than that of the second auxiliary color sub-pixel 122 enhances the brightness of the first auxiliary color sub-pixel 121. Consequently, after mixing partial light of the primary color sub-pixel 11, the first auxiliary color sub-pixel 121, and the second auxiliary color sub-pixel 122 into white light, the brightness is also increased. Thus, the brightness of pixel 1 is increased and subsequently increase the brightness of the display panel.

Typically, the human eye sensitivity to the green sub-pixel is greater than that to the red sub-pixel. The human eye sensitivity to the red sub-pixel is greater than that to the blue sub-pixel. When the primary color sub-pixel 11 includes the red sub-pixel and the auxiliary color sub-pixels 12 include the green sub-pixel and the blue sub-pixel, the area of the green sub-pixel is arranged to be larger than that of the blue sub-pixel. This increases the brightness of the green sub-pixel. When the primary color sub-pixel 11 includes the green sub-pixel and the auxiliary color sub-pixels 12 include the blue sub-pixel and the red sub-pixel, the area of the red sub-pixel is arranged to be larger than that of the blue sub-pixel. This increases the brightness of the red sub-pixel. When the primary color sub-pixel 11 includes the blue sub-pixel and the auxiliary color sub-pixels 12 include the green sub-pixel and the red sub-pixel, the area of the green sub-pixel is arranged to be larger than that of the red sub-pixel. This increases the brightness of the green sub-pixel. It should be noted that the area of the first auxiliary color sub-pixel 121 and the area of the second auxiliary color sub-pixel 122 need to comprehensively consider the human eye sensitivity and take into account the color balance of the display panel. This avoids significant color deviation caused by an excessively large area of a particular auxiliary color sub-pixel.

FIG. 4 provides a schematic diagram of another pixel arrangement of a display panel according to embodiments of the present disclosure. Optionally, as shown in FIG. 4, the auxiliary color sub-pixels 12 in pixel 1 includes at least a third auxiliary color sub-pixel 123 and a fourth auxiliary color sub-pixel 124. The area of the third auxiliary color sub-pixel 123 is greater than the area of the fourth auxiliary color sub-pixel 124. The luminous efficiency of the third auxiliary color sub-pixel 123 is lower than that of the fourth auxiliary color sub-pixel 124.

Specifically, as shown in FIG. 4, when it needs to increase the brightness of the display panel, since the luminous efficiency of the third auxiliary color sub-pixel 123 is lower than that of the fourth auxiliary color sub-pixel 124, the brightness of the third auxiliary color sub-pixel 123 is lower. Therefore, the area of the third auxiliary color sub-pixel 123 is set to be larger than that of the fourth auxiliary color sub-pixel 124. By enlarging the area of the third auxiliary color sub-pixel 123, its luminous efficiency is increased. After mixing partial light of the primary color sub-pixel 11, the third auxiliary color sub-pixel 123, and the fourth auxiliary color sub-pixel 124 into white light, the brightness is also increased. This enhances the brightness of pixel 1 and subsequently increases the brightness of the display panel.

In general, the luminous efficiency of the blue sub-pixel is greater than that of the green sub-pixel, and the luminous efficiency of the green sub-pixel is greater than that of the red sub-pixel. When the primary color sub-pixel 11 includes the red sub-pixel as well as the auxiliary color sub-pixels 12 include the green sub-pixel and the blue sub-pixel, the area of the green sub-pixel is set to be larger than that of the blue sub-pixel. When the primary color sub-pixel 11 includes the green sub-pixel as well as the auxiliary color sub-pixels 12 include the blue pixel and the red sub-pixel, the area of the red sub-pixel is set to be larger than that of the blue sub-pixel. When the primary color sub-pixel 11 includes the blue sub-pixel and the auxiliary color sub-pixels 12 include the green sub-pixel and the red sub-pixel, the area of the red sub-pixel is set to be larger than that of the green sub-pixel.

In some embodiments, when considering the comprehensive impact of human eye sensitivity and luminous efficiency on brightness, if the primary color sub-pixel 11 includes the red sub-pixel and the auxiliary color sub-pixels 12 include the green sub-pixel and the blue sub-pixel, the area of the green sub-pixel is set to be larger than that of the blue sub-pixel, as the human eye sensitivity to the green sub-pixel is greater than that to the blue sub-pixel, and the luminous efficiency of the green sub-pixel is lower than that of the blue sub-pixel. This enhances the brightness of pixel 1. Similarly, if the primary color sub-pixel 11 includes the green sub-pixel and the auxiliary color sub-pixels 12 include the red sub-pixel and the blue sub-pixel, the area of the red sub-pixel is set to be larger than that of the blue sub-pixel to enhance the brightness of pixel 1, as the human eye sensitivity to the red sub-pixel is greater than that to the blue sub-pixel, and the luminous efficiency of the red sub-pixel is lower than that of the blue sub-pixel. In some implementations, when the primary color sub-pixel 11 includes a blue sub-pixel and the auxiliary color sub-pixels 12 include the green sub-pixel and the red sub-pixel, the human eye sensitivity of the green sub-pixel is greater than that of the red sub-pixel, and the luminous efficiency of the red sub-pixel is less than that of the green sub-pixel. The impact of human eye sensitivity and luminous efficiency on brightness can be comprehensively considered, and the area of green sub-pixel and the area of red sub-pixel are designed to improve the brightness of pixel 1.

It should be noted that in the above embodiments, the adjustment of the area of each color sub-pixel requires comprehensive consideration of the chromaticity balance of the display panel. On the premise of ensuring the chromaticity balance required by the display effect, the area of each color sub-pixel is adjusted accordingly.

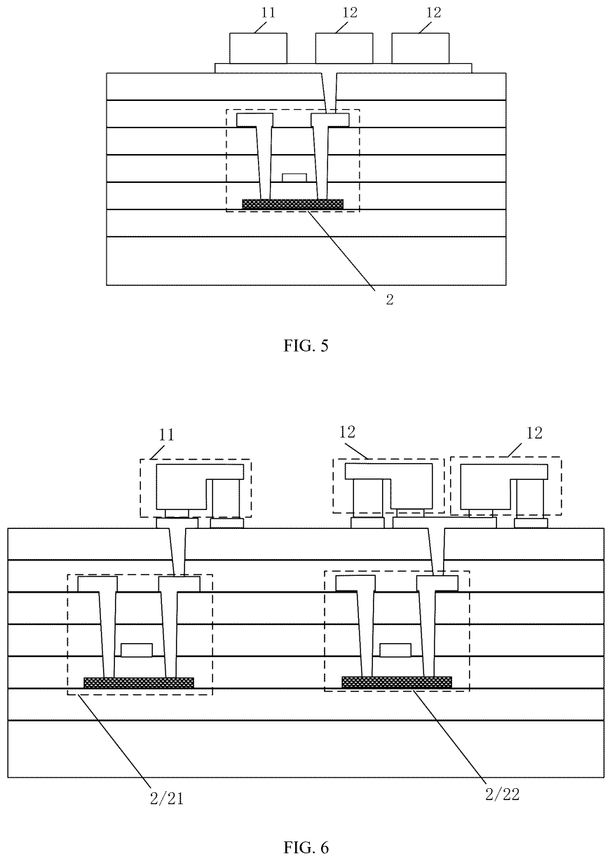

FIG. 5 provides a schematic diagram of a cross-sectional structure of a display panel according to embodiments of the present disclosure. Optionally, as shown in FIG. 5, the primary color sub-pixel 11 and each auxiliary color sub-pixel 12 in pixel 1 are connected to a same driving circuit 2.

Specifically, as shown in FIG. 5, the driving circuit 2 is used to drive pixel 1 to emit light. In order to reduce the occupied area of the driving circuit 2 and simplify the circuit design of the display panel, the primary color sub-pixel 11 and each auxiliary color sub-pixel 12 can be connected to the same driving circuit 2. This driving circuit 2 can simultaneously drive the primary color sub-pixel 11 and each auxiliary color sub-pixel 12 to emit light. When the primary color sub-pixel 11 of pixel 1 is activated, the auxiliary color sub-pixels 12 of the pixel 1 are also activated.

FIG. 6 provides a schematic diagram of another cross-sectional structure of a display panel according to embodiments of the present disclosure. Optionally, as shown in FIG. 6, the primary color sub-pixel 11 and the auxiliary color sub-pixels 12 in pixel 1 are connected to different driving circuits 2.

Specifically, as shown in FIG. 6, the primary color sub-pixel 11 and the auxiliary color sub-pixels 12 can be connected to different driving circuits 2. Different driving circuits 2 can respectively drive the primary color sub-pixel 11 and the auxiliary color sub-pixels 12. Based on the requirements of the display panel for brightness and NTSC color gamut saturation, separate control of the primary color sub-pixel 11 and the auxiliary color sub-pixels 12 can be achieved. For example, when it is necessary to increase the brightness of pixel 1, the driving current provided by the driving circuit 2 connected to the primary color sub-pixel 11 can be kept constant, while the driving current provided by the driving circuit 2 connected to the auxiliary color sub-pixels 12 can be increased to enhance the brightness of the auxiliary color sub-pixels 12. Consequently, the brightness of the white light made from mixing the partial light of the primary color sub-pixel 11 and the light of the auxiliary color sub-pixel 12 is also increased. Similarly, when it is necessary to increase the saturation of pixel 1, the driving current provided by the driving circuit 2 connected to the auxiliary color sub-pixels 12 can be kept constant, while the driving current provided by the driving circuit 2 connected to the primary color sub-pixel 11 can be increased to enhance the brightness of the primary color sub-pixel 11, thereby increasing the saturation of pixel 1.

As a result, by connecting the primary color sub-pixel 11 and the auxiliary color sub-pixels 12 in the pixel 1 to different driving circuits 2, precise adjustment of different brightness and different NTSC color gamut saturations is achieved. This improves the controllability of brightness and NTSC color gamut saturation of the display panel.

Optionally, as shown in FIG. 6, the primary color sub-pixel 11 in pixel 1 is connected to a first driving circuit 21, and each auxiliary color sub-pixel 12 in a same pixel 1 is connected to a same second driving circuit 22.

Specifically, as shown in FIG. 6, the primary color sub-pixel 11 is electrically connected to the first driving circuit 21 which is used to drive the primary color sub-pixel 11 to emit light. Each auxiliary color sub-pixel 12 is electrically connected to the second driving circuit 22 which is used to drive each auxiliary color sub-pixel 12 to emit light. FIG. 6 exemplarily shows that both auxiliary color sub-pixels 12 are connected to the second driving circuit 22. This achieves separate control of the primary color sub-pixel 11 and the auxiliary color sub-pixels 12, improving the control precision of driving current.

For example, when the primary color sub-pixel 11 is the red sub-pixel and the auxiliary color sub-pixels 12 are the green sub-pixel and the blue sub-pixel, the red sub-pixel is connected to the first driving circuit 21, while the green sub-pixel and the blue sub-pixel are connected to the second driving circuit 22. When the primary color sub-pixel 11 is the green sub-pixel and the auxiliary color sub-pixels 12 are the red sub-pixel and the blue sub-pixel, the green sub-pixel is connected to the first driving circuit 21, while the red sub-pixel and the blue sub-pixel are connected to the second driving circuit 22. When the primary color sub-pixel 11 is the blue sub-pixel and the auxiliary color sub-pixels 12 are the green sub-pixel and the red sub-pixel, the blue sub-pixel is connected to the first driving circuit 21, while the green sub-pixel and the red sub-pixel are connected to the second driving circuit 22.

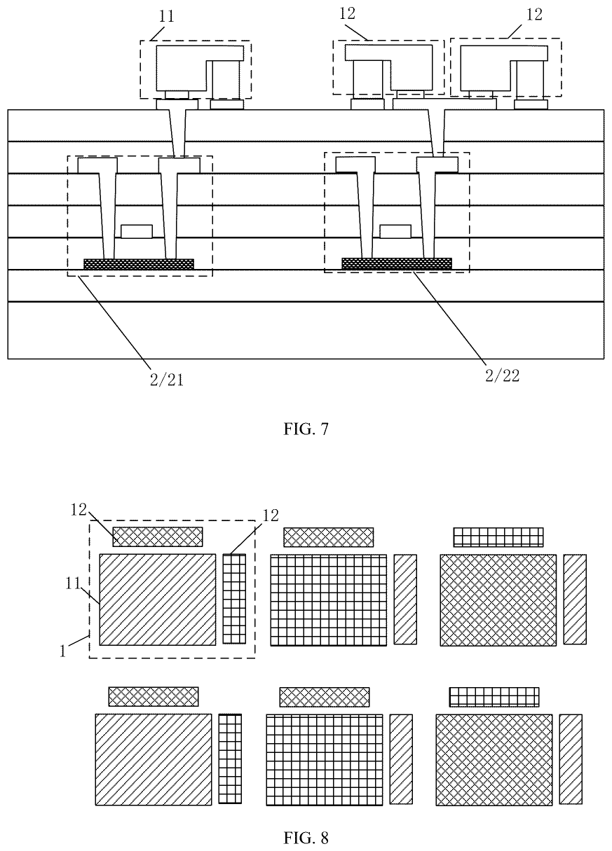

FIG. 7 provides a schematic diagram of another cross-sectional structure of a display panel according to embodiments of the present disclosure. Optionally, as shown in FIG. 7, the primary color sub-pixel 11 and each auxiliary color sub-pixel 12 in pixel 1 are connected to different driving circuits 2 in a one-to-one correspondence.

Specifically, as shown in FIG. 7, when different color sub-pixels are driven to emit light by the driving circuit 2, applicable driving currents for different color sub-pixels are different. For example, due to manufacturing process and other factors, ranges of driving currents applicable to red sub-pixel, blue sub-pixel, and green sub-pixel are not exactly the same. Additionally, the luminous efficiency of different auxiliary color sub-pixels 12 are also different. Based on the brightness requirement, the demand for driving current for auxiliary color sub-pixels 12 also varies. Therefore, the primary color sub-pixel 11 and each auxiliary color sub-pixel 12 are connected to different driving circuits 2 in a one-to-one correspondence. The driving circuit 2 connected to the primary color sub-pixel 11 provides a driving current to the primary color sub-pixel 11. Driving circuits 2 connected to different auxiliary color sub-pixels 12 provide driving currents to different auxiliary color sub-pixels 12. These driving currents can be the same or different, depending on the actual display requirements of the display panel.

FIG. 7 exemplarily shows the primary color sub-pixel 11 connected to the first driving circuit 21 and one auxiliary color sub-pixel 12 connected to the second driving circuit 22, while another auxiliary color sub-pixel 12 is connected to the third driving circuit 23.

FIG. 8 provides a schematic diagram of another pixel arrangement of a display panel according to embodiments of the present disclosure. Optionally, as shown in FIG. 8, the auxiliary color sub-pixels 12 in the same pixel 1 are located on different sides of the primary color sub-pixel 11.

Specifically, FIG. 8 shows six pixels 1. One auxiliary sub-pixel 12 is set in a row direction and one auxiliary sub-pixel 12 is set in a column direction of the primary color sub-pixel 11. By setting auxiliary color sub-pixels 12 on different sides of the primary color sub-pixel 11, it matches the layout design of the display panel and satisfies the aspect ratio of the display panel using the row-column arrangement of the primary color sub-pixel 11 and the auxiliary color sub-pixels 12. On the other hand, the auxiliary color sub-pixels 12 are added in both the row direction and the column direction of the display panel to prevent adding the auxiliary color sub-pixels 12 only in the row direction, causing a long wiring in the row direction. This also prevents adding the auxiliary color sub-pixels 12 only in the column direction, causing a long wiring in the column direction. It also avoids issue of too many auxiliary color sub-pixels 12 in the row direction, causing a large voltage drop of pixel 1 in the row direction. This also avoids the issue of too many auxiliary color sub-pixels 12 in the column direction, causing a large voltage drop of pixel 1 in the column direction. This improves the display uniformity of the display panel.

FIG. 8 exemplarily illustrates one arrangement of the primary color sub-pixel 11 and the auxiliary color sub-pixels 12. It should be noted that the arrangement of auxiliary color sub-pixels 12 in the row direction and the column direction is not limited to the manner shown in FIG. 8. The arrangement can be set according to the display requirements of the display panel. The present disclosure does not impose limitations on this aspect.

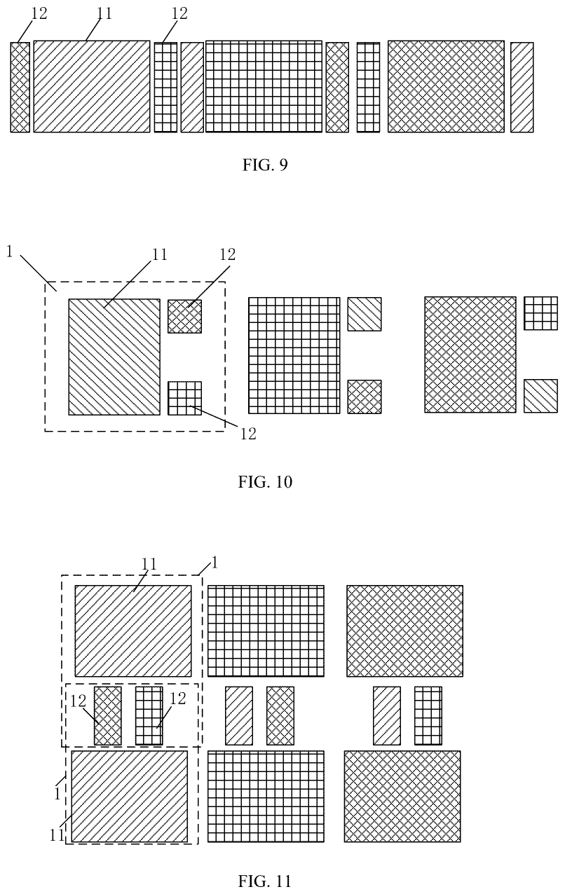

FIG. 9 is a schematic diagram of another pixel arrangement of a display panel provided by embodiments of the present disclosure. Optionally, as shown in FIG. 9, the auxiliary color sub-pixels 12 in a same pixel 1 are located on opposite sides of the primary color sub-pixel 11.

FIG. 9 exemplarily shows the arrangement where the primary color sub-pixel 11 is set as the red sub-pixel, and the auxiliary color sub-pixels 12 are the blue sub-pixel and the green sub-pixel. The blue sub-pixel and the green sub-pixel are positioned on both sides of the red sub-pixel in the column direction. When the primary color sub-pixel 11 is the green sub-pixel, and the auxiliary color sub-pixels 12 are the blue sub-pixel and the red sub-pixel, the blue sub-pixel and the red sub-pixel are positioned on both sides of the green sub-pixel in the column direction. When the primary color sub-pixel 11 is the blue sub-pixel, and the auxiliary color sub-pixels 12 are the green sub-pixel and the red sub-pixel, the green sub-pixel and the red sub-pixel are positioned on both sides of the blue sub-pixel in the column direction.

It should be noted that the arrangement of the auxiliary color sub-pixels 12 is not limited to the manner shown in FIG. 9. Two columns of auxiliary color sub-pixels 12 on the left and right of the primary color sub-pixel 11 in FIG. 9 can also be exchanged to meet the display requirements of the display panel. This is not limited in embodiments of the present disclosure.

Therefore, by arranging the auxiliary color sub-pixels 12 on opposite sides of the primary color sub-pixel 11 in the same pixel 1, the resulting white light mixed by the auxiliary color sub-pixels 12 and the primary color sub-pixel 11 becomes more uniform.

Optionally, as shown in FIG. 1, the auxiliary color sub-pixels 12 in the same pixel 1 are located on a same side of the primary color sub-pixel 11.

For example, as shown in FIG. 1, for a display panel with more pixels 1 in the row direction, if an auxiliary color sub-pixel 12 is added between adjacent two columns of pixels 1, the quantity of sub-pixels in the row direction will be further increased, which can cause excessive load in the row direction. Therefore, in some embodiments, the auxiliary color sub-pixels 12 are positioned above or below each row of primary color sub-pixels 11, avoiding an increase in the quantity of sub-pixels in the row direction and issues with signal attenuation caused by excessive load. The pixel arrangement shown in FIG. 1, for example, can be applied in a vehicle central control screen with a large horizontal size.

FIG. 10 provides a schematic diagram of another pixel arrangement of a display panel according to embodiments of the present disclosure. As shown in FIG. 10, for a display panel with more pixels 1 in the column direction, if the auxiliary color sub-pixel 12 is added between adjacent two rows of primary color sub-pixels 11, the quantity of sub-pixels in the column direction will be further increased, which can cause excessive load in the column direction. Therefore, in the present disclosure, the auxiliary color sub-pixels 12 are positioned to the left or right of each column of primary color sub-pixels 11, avoiding an increase in the quantity of sub-pixels in the column direction and issues with signal attenuation caused by excessive load.

It should be noted that in practical applications, the arrangement of auxiliary color sub-pixels 12 between adjacent rows or adjacent columns of primary color sub-pixels 11 can be selected according to the quantity of channels of the display panel driving chip.

FIG. 11 provides a schematic diagram of another pixel arrangement of a display panel according to embodiments of the present disclosure. As shown in FIG. 11, primary color sub-pixels 11 of a same color are arranged along the column direction. Adjacent two rows of pixels 1 share an auxiliary color sub-pixel 12, and the shared auxiliary color sub-pixel 12 is located between the primary color sub-pixels 11 of adjacent two rows of pixels 1.

Specifically, as shown in FIG. 11, primary color sub-pixels 11 of a same color are arranged along the column direction, and the auxiliary color sub-pixels 12 of adjacent two rows of the primary color sub-pixels 11 share a same color. Therefore, auxiliary color sub-pixels 12 are arranged between primary color sub-pixels 11 of adjacent two rows of pixels 1. FIG. 11 exemplarily shows two rows of primary color sub-pixels 11, where the primary color sub-pixels 11 of the first row of pixels 1 share auxiliary color sub-pixels 12 with the primary color sub-pixels 11 of the second row of pixels 1. Light from the auxiliary color sub-pixels 12 and partial light from the primary color sub-pixels 11 of the first row of pixels 1 are mixed into white. The first row of pixels 1 presents the primary color. Similarly, light from the auxiliary color sub-pixels 12 and partial light from the primary color sub-pixels 11 of the second row of pixels 1 are mixed into white. The second row of pixels 1 also present the primary color.

Exemplarily, when the primary color sub-pixel 11 is the red sub-pixel and the auxiliary color sub-pixels 12 are the blue sub-pixel and the green sub-pixel, the blue sub-pixel and the green sub-pixel are positioned in a same row between adjacent two rows of red sub-pixels. This enables adjacent rows of red sub-pixels to share the blue sub-pixel and the green sub-pixel. When the primary color sub-pixel 11 is the green sub-pixel and the auxiliary color sub-pixels 12 are the red sub-pixel and the blue sub-pixel, the red sub-pixel and the blue sub-pixel are positioned in the same row between adjacent two rows of green sub-pixels. This enables adjacent rows of green sub-pixels to share the red sub-pixel and the blue sub-pixel. When the primary color sub-pixel 11 is the blue sub-pixel and the auxiliary color sub-pixels 12 are the red sub-pixel and the green sub-pixel, the red sub-pixel and the green sub-pixel are positioned in a same row between adjacent two rows of the red sub-pixel and the green sub-pixel. This enables adjacent rows of blue sub-pixels to share the red sub-pixel and the green sub-pixel.

Therefore, by sharing the auxiliary color sub-pixels 12, the original two auxiliary color sub-pixels 12 respectively arranged between adjacent two rows are integrated into one auxiliary color sub-pixel 12. Space between the two auxiliary color sub-pixels 12 is utilized to increase the area of the auxiliary color sub-pixels 12. A large area of the auxiliary color sub-pixel 12 leads to a great luminous efficiency. Thus, this increases the brightness of the auxiliary color sub-pixel 12, thereby increasing the brightness of the pixel 1 and the display panel. Additionally, sharing the auxiliary color sub-pixels 12 will reduce the quantity of auxiliary color sub-pixels 12, thereby reducing the quantity of driving circuits 2 and driving data lines arranged corresponding to the auxiliary color sub-pixels 12. This simplifies the design of the display panel. Moreover, by sharing the auxiliary color sub-pixel 12, the space between the original auxiliary color sub-pixel 12 and the upper row of primary color sub-pixels 11 can be eliminated, thereby saving space.

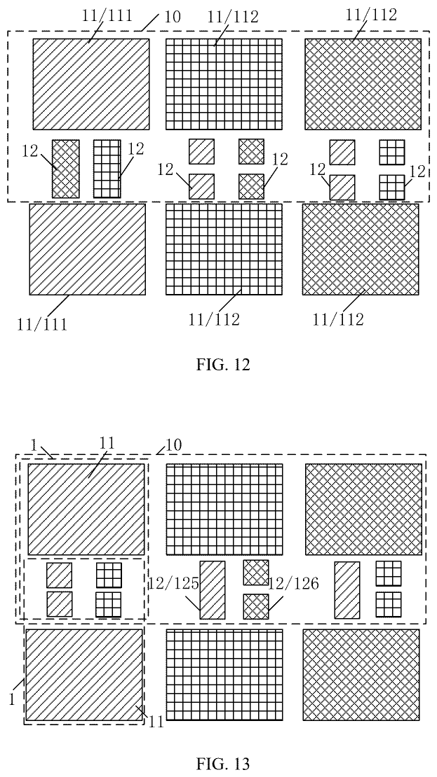

FIG. 12 provides a schematic diagram of another pixel arrangement of a display panel according to embodiments of the present disclosure. Optionally, as shown in FIG. 12, the pixel unit 10 has at least a first primary color sub-pixel 111 and a second primary color sub-pixel 112. The auxiliary color sub-pixels 12 are positioned between primary color sub-pixels 11 of adjacent two two rows of pixels 1. The luminous efficiency of the first primary color sub-pixel 111 is less than that of the second primary color sub-pixel 112. The first primary color sub-pixel 111 in adjacent two rows of pixels 1 share the auxiliary color sub-pixels 12. Second primary color sub-pixels 112 in adjacent two rows of pixels 1 correspond to their respective auxiliary color sub-pixels 12. The area of the shared auxiliary color sub-pixels 12 are greater than that of the non-shared auxiliary color sub-pixels 12.

Specifically, as shown in FIG. 12, when the luminous efficiency of the first primary color sub-pixel 111 is less than that of the second primary color sub-pixel 112, to enhance the brightness of the first primary color sub-pixel 111, the first primary color sub-pixels 111 in adjacent two rows of pixels 1 share the auxiliary color sub-pixels 12. The second primary color sub-pixels 112 in adjacent two rows of pixels 1 do not share the auxiliary color sub-pixels 12. Instead, the second primary color sub-pixels 112 in adjacent two rows of pixels 1 correspond to their respective auxiliary color sub-pixels 12. The first row of second primary color sub-pixels 112 corresponding to one row of auxiliary color sub-pixels 12 and the second row of second primary color sub-pixels 112 corresponding to another row of auxiliary color sub-pixels 12. FIG. 12 exemplarily shows the shared auxiliary color sub-pixels 12 are positioned between the first primary color sub-pixels 111 of adjacent two rows of pixels 1 and arranged in one row. The non-shared auxiliary color sub-pixels 12 are positioned between the second primary color sub-pixels 112 of adjacent two rows of pixels 1 and arranged in two rows. There is a space between the two rows of non-shared auxiliary color sub-pixels 12. The shared auxiliary color sub-pixels 12 utilize the space between two rows of non-shared auxiliary color sub-pixels 12. The area of the shared auxiliary color sub-pixels 12 is greater than that of the non-shared auxiliary color sub-pixels 12. Consequently, the luminous efficiency of the shared auxiliary color sub-pixels 12 is greater than that of the non-shared auxiliary color sub-pixels 12. This improves the luminous efficiency of the first primary color sub-pixels 111 that have a larger area of the shared auxiliary color sub-pixels 12. Thus, this enhances the brightness of the first primary color sub-pixel 111 and compensates for the brightness difference between the first primary color sub-pixel 111 and the second primary color sub-pixel 112.

Exemplarily, as shown in FIG. 12, when the first primary color sub-pixel 111 is a red sub-pixel and the second primary color sub-pixel 112 is a green sub-pixel. The luminous efficiency of the red sub-pixel is less than that of the green sub-pixel. The red sub-pixels in adjacent two rows of pixels 1 share green sub-pixels and blue sub-pixels. There are two rows of green and blue sub-pixels between adjacent two rows of green sub-pixels. Each row of green sub-pixels corresponds to their respective red sub-pixels and blue sub-pixels. Areas of the green sub-pixels and the blue sub-pixels between adjacent two rows of red sub-pixels and are greater than those of the red sub-pixels and the blue sub-pixels between adjacent two rows of green sub-pixels.

As shown in FIG. 12, when the first primary color sub-pixel 111 is, for example, the red sub-pixel, the second primary color sub-pixel 112 is, for example, the blue sub-pixel, the luminous efficiency of the red sub-pixel is less than that of the blue sub-pixel. The red sub-pixels of adjacent two rows of pixels 1 share green and blue sub-pixels. There are two rows of green and red sub-pixels between adjacent two rows of blue sub-pixels. Each row of blue sub-pixels corresponds to its own green sub-pixels and red sub-pixels. Areas of the green sub-pixels and the blue sub-pixels between adjacent two rows of red sub-pixels are greater than those of the red sub-pixels and the green sub-pixels between adjacent two rows of blue sub-pixels.

FIG. 13 provides a schematic diagram of another pixel arrangement of a display panel according to embodiments of the present disclosure. As shown in FIG. 13, primary color sub-pixels 11 of a same color are arranged along the column direction. Auxiliary color sub-pixels 12 are positioned between the primary color sub-pixels 11 of adjacent two rows of pixels 1. The pixel unit 10 has at least a fifth auxiliary color sub-pixel 125 and a sixth auxiliary color sub-pixel 126. The luminous efficiency of the fifth auxiliary color sub-pixel 125 is less than that of the sixth auxiliary color sub-pixel 126. The primary color sub-pixels 11 in adjacent two rows of pixels 1 share the fifth auxiliary color sub-pixel 125, while the primary color sub-pixels 11 in adjacent two rows of pixels 1 correspond to their respective sixth auxiliary color sub-pixels 126. The area of the fifth auxiliary color sub-pixel 125 is greater than that of the sixth auxiliary color sub-pixel 126.

Specifically, as shown in FIG. 13, when the luminous efficiency of the fifth auxiliary color sub-pixel 125 is less than that of the sixth auxiliary color sub-pixel 126, to enhance the luminous efficiency of the fifth auxiliary color sub-pixel 125, the area of the fifth auxiliary color sub-pixel 125 is set to be greater than that of the sixth auxiliary color sub-pixel 126, thereby improving the luminous efficiency of the fifth auxiliary color sub-pixel 125 and compensating for the brightness difference between the fifth auxiliary color sub-pixel 125 and the sixth auxiliary color sub-pixel 126.

For example, when the primary color sub-pixel 11 is the green sub-pixel, the fifth auxiliary color sub-pixel 125 is the red sub-pixel. When the sixth auxiliary color sub-pixel 126 is the blue sub-pixel, the luminous efficiency of the red sub-pixel is less than that of the blue sub-pixel. To enhance the luminous efficiency of the red sub-pixel, the area of the red sub-pixel is set to be greater than that of the blue sub-pixel. Adjacent two rows of green sub-pixels share red sub-pixels and correspond to their respective blue sub-pixels. The first row of green sub-pixels corresponds to one row of blue sub-pixels, and the second row of green sub-pixels corresponds to another row of blue sub-pixels.

When the primary color sub-pixel 11 is the blue sub-pixel, the fifth auxiliary color sub-pixel 125 is the red sub-pixel, and the sixth auxiliary color sub-pixel 126 is the green sub-pixel, the luminous efficiency of the red sub-pixel is less than that of the green sub-pixel. To enhance the luminous efficiency of the red sub-pixel, the area of the red sub-pixel is set to be greater than that of the green sub-pixel. Adjacent two rows of blue sub-pixels share red sub-pixels and correspond to their respective green sub-pixels. The first row of blue sub-pixels corresponds to one row of green sub-pixels, and the second row of blue sub-pixels corresponds to another row of green sub-pixels.

Optionally, as shown in FIG. 2, the display panel includes a plurality of pixel units 10, each pixel unit has a pixel 1. The driving current of the primary color sub-pixel 11 of the pixel 1 is greater than the driving current of each auxiliary color sub-pixel 12.

FIG. 2 exemplarily shows that the areas of the primary color sub-pixel 11 and each auxiliary color sub-pixel 12 are equal. When displaying a primary color, the primary color sub-pixel 11 is turned on while the other color sub-pixels are turned off. For example, when displaying a red image, the red sub-pixel is turned on while the green sub-pixel and the blue sub-pixel are turned off. When displaying a green image, the green sub-pixel is turned on while the red sub-pixel and blue sub-pixel are turned off. When displaying a blue image, the blue sub-pixel is turned on while the green sub-pixel and the red sub-pixel are turned off. To improve the brightness of the pixel 1, embodiments of the present disclosure can set sub-pixels of different colors than the primary color sub-pixel in a same pixel 1 as auxiliary color sub-pixels 12. When the primary color sub-pixel 11 is turned on, the auxiliary color sub-pixels 12 are also turned on. Light from the auxiliary color sub-pixels 12 is mixed with the partial light from the primary color sub-pixel 11 to produce white light. Sacrificing the saturation of part of the primary color sub-pixel 11 and reducing the overall NTSC color gamut saturation of the display panel within a certain range, the brightness of the pixel 1 is improved. Additionally, the driving current of the primary color sub-pixel 11 is greater than the driving current of each auxiliary color sub-pixel 12, ensuring that the brightness of the primary color sub-pixel 11 is greater than that of each auxiliary color sub-pixel 12, thus maintaining the primary color of the pixel 1.

For example, when the pixel 1 needs to display red, the red sub-pixel serves as the primary color sub-pixel 11, while the green and blue sub-pixels serve as the auxiliary color sub-pixels 12. The green light emitted by the green sub-pixel, the blue light emitted by the blue sub-pixel, and the partial red light emitted by the red sub-pixel are mixed to form white light, thereby enhancing the brightness of the display panel. The driving current of the red sub-pixel is greater than that of the blue sub-pixel, and the driving current of the red sub-pixel is greater than that of the green sub-pixel. This ensures that the red sub-pixel has the highest brightness and that the pixel 1 displays red.

When the pixel 1 needs to display green, the green sub-pixel serves as the primary color sub-pixel 11, while the red and blue sub-pixels serve as the auxiliary color sub-pixels 12. The red light emitted by the red sub-pixel, the blue light emitted by the blue sub-pixel, and the partial green light emitted by the green sub-pixel are mixed to form white light, thereby enhancing the brightness of the display panel. The driving current of the green sub-pixel is greater than that of the blue sub-pixel, and the driving current of the green sub-pixel is greater than that of the red sub-pixel. This ensures that the green sub-pixel has the highest brightness and that the pixel 1 displays green.

When the pixel 1 needs to display blue, the blue sub-pixel serves as the primary color sub-pixel 11, while the red and green sub-pixels serve as the auxiliary color sub-pixels 12. The green light emitted by the green sub-pixel, the red light emitted by the red sub-pixel, and the partial blue light emitted by the blue sub-pixel are mixed to form white light, thereby enhancing the brightness of the display panel. The driving current of the blue sub-pixel is greater than that of the green sub-pixel, and the driving current of the blue sub-pixel is greater than that of the red sub-pixel. This ensures that the blue sub-pixel has the highest brightness and that the pixel 1 displays blue.

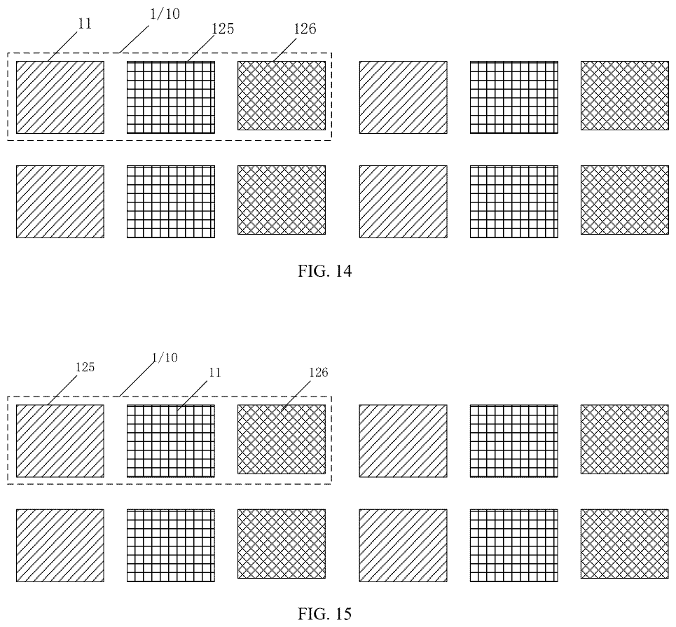

FIG. 14 provides a schematic diagram of another pixel arrangement of a display panel provided by embodiments of the present disclosure. As shown in FIG. 14, the auxiliary color sub-pixel 12 in pixel 1 includes at least a fifth auxiliary color sub-pixel 125 and a sixth auxiliary color sub-pixel 126. The driving current of the fifth auxiliary color sub-pixel 125 is greater than that of the sixth auxiliary color sub-pixel 126. The human eye sensitivity to the fifth auxiliary color sub-pixel 125 is greater than that to the sixth auxiliary color sub-pixel 126.

Specifically, a large driving current corresponds to a high brightness of a corresponding pixel 1. When it is necessary to increase the brightness of the display panel, since the human eye sensitivity to the fifth auxiliary color sub-pixel 125 is higher, a larger driving current for the fifth auxiliary color sub-pixel 125 will result in a more noticeable increase in the brightness of the display panel, making a greater contribution to the overall brightness. Therefore, setting the driving current of the fifth auxiliary color sub-pixel 125 greater than that of the sixth auxiliary color sub-pixel 126 enhances the brightness of the fifth auxiliary color sub-pixel 125. Thus, this increases the brightness of the display panel.

The human eye sensitivity to the green sub-pixel is greater than that to the red sub-pixel, and the human eye sensitivity to the red sub-pixel is greater than that to the blue sub-pixel. FIG. 14 exemplarily sets the primary color sub-pixel 11 as the red sub-pixel, the fifth auxiliary color sub-pixel 125 as the green sub-pixel, and the sixth auxiliary color sub-pixel 126 as the blue sub-pixel. The transparency of the fifth auxiliary color sub-pixel 125 is set to be less than that of the sixth auxiliary color sub-pixel 126, representing that the driving current of the green sub-pixel is greater than that of the blue sub-pixel, thereby enhancing the brightness of the green sub-pixel.

FIG. 15 provides a schematic diagram of another pixel arrangement of a display panel according to embodiments of the present disclosure. FIG. 15 exemplarily shows that when the primary color sub-pixel 11 includes a green sub-pixel, the fifth auxiliary color sub-pixel 125 is a red sub-pixel, and the sixth auxiliary color sub-pixel 126 is a blue sub-pixel. In FIG. 15, the transparency of the fifth auxiliary color sub-pixel 125 is set to be less than that of the sixth auxiliary color sub-pixel 126, representing that the driving current of the red sub-pixel is greater than that of the blue sub-pixel, thus enhancing the brightness of the red sub-pixel.

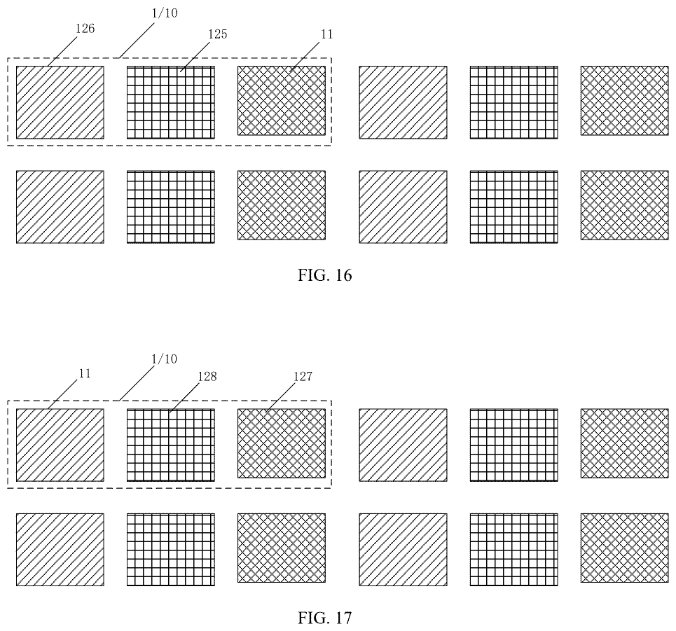

FIG. 16 is a schematic diagram of another pixel arrangement of a display panel according to embodiments of the present disclosure. FIG. 16 exemplarily shows that when the primary color sub-pixel 11 includes the blue sub-pixel, the fifth auxiliary color sub-pixel 125 is the green sub-pixel, and the sixth auxiliary color sub-pixel 126 is the red sub-pixel. In FIG. 16, the transparency of the fifth auxiliary color sub-pixel 125 is set to be less than that of the sixth auxiliary color sub-pixel 126, representing that the driving current of the green sub-pixel is greater than that of the red sub-pixel, thus enhancing the brightness of the green sub-pixel.

FIG. 17 is a schematic diagram of another pixel arrangement of a display panel according to embodiments of the present disclosure. As shown in FIG. 17, the auxiliary color sub-pixels 12 in pixel 1 include at least a seventh auxiliary color sub-pixel 127 and an eighth auxiliary color sub-pixel 128. The driving current of the seventh auxiliary color sub-pixel 127 is greater than that of the eighth auxiliary color sub-pixel 128. The luminous efficiency of the seventh auxiliary color sub-pixel 127 is less than that of the eighth auxiliary color sub-pixel 128.

Specifically, as shown in FIG. 17, when it is necessary to increase the brightness of the display panel, since the luminous efficiency of the seventh auxiliary color sub-pixel 127 is less than that of the eighth auxiliary color sub-pixel 128, the brightness of the seventh auxiliary color sub-pixel 127 is lower. Therefore, the driving current of the seventh auxiliary color sub-pixel 127 is set to be greater than that of the eighth auxiliary color sub-pixel 128. By increasing the driving current of the seventh auxiliary color sub-pixel 127, the luminous efficiency of the seventh auxiliary color sub-pixel 127 is increased. After the partial light of the primary color sub-pixel 11, the seventh auxiliary color sub-pixel 127, and the eighth auxiliary color sub-pixel 128 are mixed into white light, the brightness will also increase, thereby increasing the brightness of the pixel 1 and the display panel.

The luminous efficiency of the blue sub-pixel is greater than that of the green sub-pixel, and the luminous efficiency of the green sub-pixel is greater than that of the red sub-pixel. FIG. 17 exemplarily shows when the primary color sub-pixel 11 to be the red sub-pixel, the seventh auxiliary color sub-pixel 127 is the green sub-pixel, and the eighth auxiliary color sub-pixel 128 is the blue sub-pixel, in FIG. 17, the transparency of the seventh auxiliary color sub-pixel 127 is set to be less than that of the eighth auxiliary color sub-pixel 128, representing that the driving current of the green sub-pixel is greater than that of the blue sub-pixel, thus enhancing the brightness of the green sub-pixel.

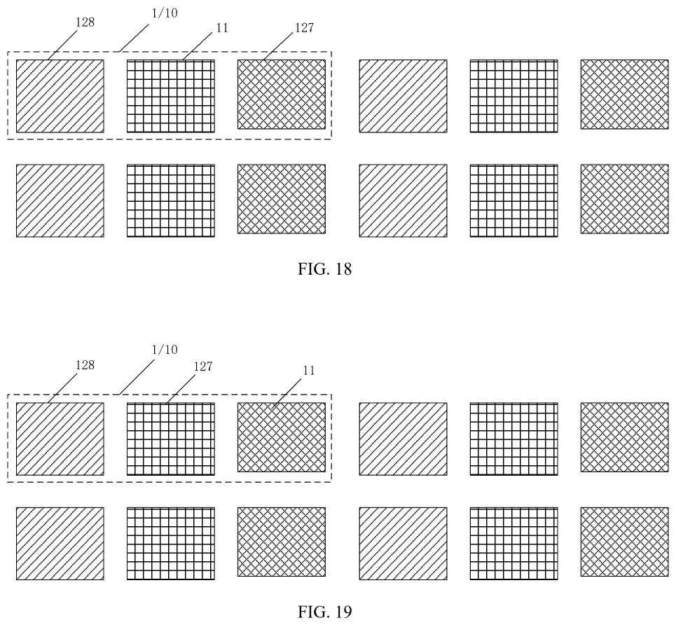

FIG. 18 is a schematic diagram of another pixel arrangement of a display panel according to embodiments of the present disclosure. FIG. 18 exemplarily shows that when the primary color sub-pixel 11 includes the green sub-pixel, the seventh auxiliary color sub-pixel 127 is the red sub-pixel, and the eighth auxiliary color sub-pixel 128 is the blue sub-pixel, in FIG. 18, the transparency of the seventh auxiliary color sub-pixel 127 is set to be less than that of the eighth auxiliary color sub-pixel 128, representing that the driving current of the red sub-pixel is greater than that of the blue sub-pixel, thus enhancing the brightness of the red sub-pixel.

FIG. 19 is a schematic diagram of another pixel arrangement of a display panel according to embodiments of the present disclosure. FIG. 19 exemplarily shows that when the primary color sub-pixel 11 includes the blue sub-pixel, the seventh auxiliary color sub-pixel 127 is the green sub-pixel, and the eighth auxiliary color sub-pixel 128 is the red sub-pixel, in FIG. 19, the transparency of the seventh auxiliary color sub-pixel 127 is set to be less than that of the eighth auxiliary color sub-pixel 128, representing that the driving current of the red sub-pixel is greater than that of the green sub-pixel, thus enhancing the brightness of the red sub-pixel.

When comprehensively considering the impact of human eye sensitivity and luminous efficiency on brightness, the primary color sub-pixel 11 includes the red sub-pixel, and the auxiliary color sub-pixels 12 include the green sub-pixel and the blue sub-pixel. Since the human eye sensitivity to the green sub-pixel is greater than that to the blue sub-pixel and the luminous efficiency of the green sub-pixel is less than that of the blue sub-pixel, the driving current of the green sub-pixel can be set to be greater than that of the blue sub-pixel, thereby increasing the brightness of the pixel 1. Similarly, when the primary color sub-pixel 11 includes the green sub-pixel and the auxiliary color sub-pixels 12 include the red sub-pixel and the blue sub-pixel, since the human eye sensitivity to the red sub-pixel is greater than that to the blue sub-pixel, and the luminous efficiency of the red sub-pixel is less than that of the blue sub-pixel, the driving current of the red sub-pixel can be set to be greater than that of the blue sub-pixel, thereby increasing the brightness of the pixel 1. When the primary color sub-pixel 11 includes the blue sub-pixel and the auxiliary color sub-pixels 12 include the green sub-pixel and the red sub-pixel, the human eye sensitivity to the green sub-pixel is greater than that to the red sub-pixel, and the luminous efficiency of the red sub-pixel is less than that of the green sub-pixel, considering the impact of the human eye sensitivity and luminous efficiency on the brightness, the driving currents of the green sub-pixel and the red sub-pixel are adjusted to enhance the brightness of the pixel 1.

It should be noted that in the above embodiments, the adjustment of the driving current of each color sub-pixel needs to comprehensively consider the chromaticity balance of the display panel. On the premise of ensuring the chromaticity balance required by the desired display effect, the driving current of each color sub-pixel is adjusted to a certain extent.

Optionally, the sub-pixel 1 is a micro light-emitting diode (micro-LED) or an organic light-emitting diode (OLED). When using liquid crystal display (LCD) as the sub-pixel 1, it is known from the light-emitting principle of LCD that LCD cannot emit light on its own and needs to be paired with a backlight source to emit light. The backlight source emits light through the liquid crystal layer and CF film, and the light utilization rate is low. To project in a driving environment, low brightness will result in poor readability for users. Therefore, it is necessary to increase the brightness of the LCD to ensure the display effect. To increase the brightness of the LCD, the CF film can be thinned to increase transmittance and thereby brightness. However, the NTSC color gamut saturation of LCD itself is not high. Thinning the CF film will further reduce its NTSC color gamut saturation, resulting in poor display effect. In addition, LCD needs to be used with a polarizer, so the light emitted by LCD is a linearly polarized light. For example, when the light transmitted through the upper polarizer of the LCD is P light, due to the low reflectivity of P light, the amount of light that can be received by the naked eye is limited. Generally, LCD needs to emit S light. However, S light cannot pass through sunglasses, resulting in significant limitations on the use of LCD.

To solve the above problems, embodiments of the present disclosure use micro-LED or OLED as the sub-pixel 1. Micro-LED and OLED have higher NTSC color gamut saturation. For example, HUD products require a display panel with NTSC color gamut saturation of 70%. Micro-LED and OLED both have NTSC color gamut saturations of 100%. Therefore, partial NTSC color gamut saturation of micro-LED and OLED can be sacrificed to improve the brightness of micro-LED and OLED. This can meet the NTSC color gamut saturation requirements as well as the brightness requirements of HUD products.

Furthermore, micro-LED and OLED do not require a backlight source. When displaying a black screen, the driving circuits of micro-LED and OLED can be directly turned off to prevent them from emitting light. LCD controls the liquid crystal to not deflect when displaying a black screen, and the backlight source remains illuminated, resulting in certain brightness. Therefore, the contrast of micro-LED and OLED compared to LCD is significantly improved. Moreover, micro-LED and OLED do not require a polarizer, thus supporting the use of sunglasses.

Embodiments of the present disclosure set one of the multiple color sub-pixels of the pixel as the primary color sub-pixel, and the other sub-pixels as the auxiliary color sub-pixels. The pixel still presents the primary color, ensuring the requirements of HUD technology for NTSC color gamut saturation are met. The auxiliary color sub-pixels and the primary color sub-pixel are turned on synchronously to mix the light of the auxiliary color sub-pixels and the partial light of the primary color sub-pixels to produce white light. The use of white light increases the brightness of the pixel, thereby increasing the brightness of the display panel, allowing the display panel to meet the brightness requirements of HUD technology and improving the display effect of the display panel.

Based on the same invention concept, embodiments of the present disclosure further provide a display apparatus, including a display panel provided in any of the above embodiments. Therefore, the display apparatus has the technical features of the display panel provided by embodiments of the present disclosure and can achieve the beneficial effects of the display panel according to embodiments of the present disclosure. The similarities can be referred to the description of the display panel provided in embodiments of the present disclosure, and are not repeated here.

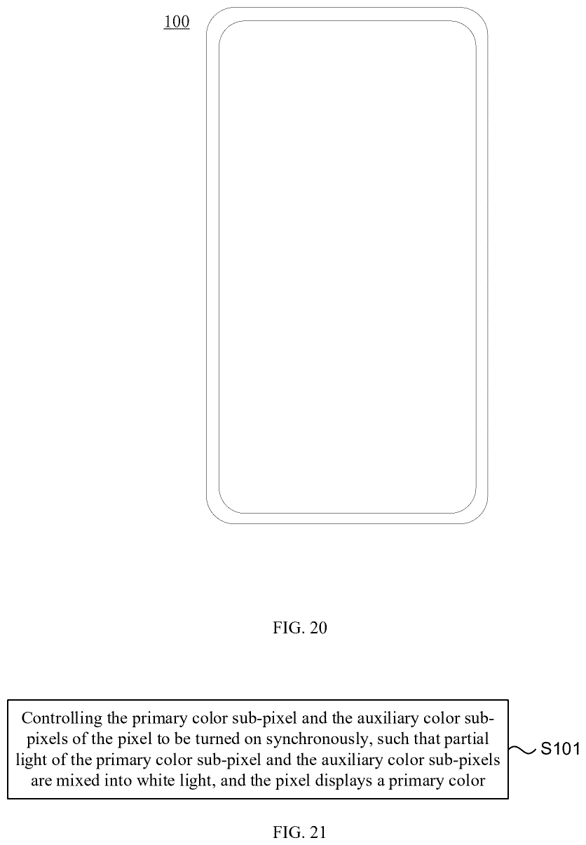

Illustratively, FIG. 20 is a schematic structural diagram of a display apparatus according to embodiments of the present disclosure. As shown in FIG. 20, the display apparatus provided in embodiments of the present disclosure includes the display panel 100 provided in any of the embodiments disclosed above. The embodiment in FIG. 20 only illustrates the display apparatus with a phone as an example, but it can be understood that the display apparatus provided in the present disclosure can be any electronic product with display function, including but not limited to the following categories: phones, televisions, laptops, desktop monitors, tablets, digital cameras, smart bracelets, smart glasses, car displays, medical equipment, industrial control equipment, touch interactive terminals, etc. Embodiments of the present disclosure are not specifically limited it.

The display apparatus provided in embodiments of the present disclosure includes the above-mentioned display panel, thereby solving the same technical issues and achieving the same technical effect, which will not be described again here.

Embodiments of the present disclosure also provides a driving method for a display panel, applicable to any of the display panels in embodiments mentioned above. FIG. 21 is a schematic flow diagram of a driving method for a display panel provided in the present disclosure. As shown in FIG. 21, the driving method for the display panel comprises:

S101, controlling the primary color sub-pixel and the auxiliary color sub-pixel of the pixel to be turned on synchronously, mixing the partial light of the primary color sub-pixel and the light of the auxiliary color sub-pixel into white light, and displaying the pixel the primary color.

Specifically, by simultaneously turning on the primary color sub-pixel and the auxiliary color sub-pixel, both emit light. Partial light of the primary color sub-pixel and light of the auxiliary color sub-pixel are mixed to form white light, which is used to enhance the brightness of the pixel, while the pixel still displays the primary color. Thus, the brightness of the pixel is increased while the NTSC color gamut saturation of the pixel meets the display requirements, thereby improving the display effect of the display panel. The specific arrangement of the primary color sub-pixel and auxiliary color sub-pixel can refer to embodiments mentioned above, and are not further described in the present disclosure.

Optionally, the display panel includes multiple pixel units, and each pixel unit includes multiple pixels. Colors of the primary color sub-pixels of a same pixel unit are different.

The driving method further includes: when the display screen is a solid color, controlling the primary color sub-pixel with a same color of the display screen to be turned on. At the same time, it controls at least some auxiliary color sub-pixels in each pixel with the same color of the display screen to be turned on.

FIG. 1 exemplarily shows the arrangement of the display panel according to the pixel arrangement with the primary color sub-pixels 11 as a red sub-pixel, a green sub-pixel, and a blue sub-pixel. That is, a green sub-pixel column is located between a red sub-pixel column and a blue sub-pixel column. When the display screen needs to display red, red sub-pixels in the first column of FIG. 1 are controlled to be turned on, and the auxiliary color sub-pixels corresponding to the red sub-pixels are also turned on to increase the brightness of the red sub-pixels. The green sub-pixels in the second column, as the primary color sub-pixels 11, are turned off. The red sub-pixels in the auxiliary color sub-pixels corresponding to the green sub-pixels are turned on. The blue sub-pixels in the third column serve as the primary color sub-pixels, and the red sub-pixels in the auxiliary color sub-pixels corresponding to the blue sub-pixels are turned on. Thus, based on the activation of the red sub-pixels as the primary color sub-pixels 11, further increasing the brightness of the red screen by activating the red sub-pixels 12 as the auxiliary color sub-pixels is achieved.

When the display screen needs to show green, the green sub-pixels in the second column of FIG. 1 are controlled to be turned on, and the auxiliary color sub-pixels corresponding to the green sub-pixels are all turned on to increase the brightness of the green sub-pixels. The red sub-pixels in the first column, as the primary color sub-pixels 11, are turned off. The green sub-pixels in the auxiliary color sub-pixels corresponding to the red sub-pixels are turned on. The blue sub-pixels in the third column serve as the primary color sub-pixels 11, and the green sub-pixels in the auxiliary color sub-pixels corresponding to the blue sub-pixels are turned on. Thus, based on the activation of the green sub-pixels as the primary color sub-pixels 11, further increasing the brightness of the green screen is achieved by activating the green sub-pixels as the auxiliary color sub-pixels.

When the display screen needs to show blue, the blue sub-pixels in the third column of FIG. 1 are set to be turned on, and the auxiliary color sub-pixels corresponding to the blue sub-pixels are all turned on to increase the brightness of the blue sub-pixels. The red sub-pixels in the first column, as the primary color sub-pixels 11, are turned off. The blue sub-pixels in the auxiliary color sub-pixels corresponding to the red sub-pixels are turned on. The green sub-pixels in the second column serve as the primary color sub-pixels 11, and the blue sub-pixels in the auxiliary color sub-pixels corresponding to the green sub-pixels are turned on. Thus, based on the activation of the blue sub-pixels as the primary color sub-pixels 11, further increasing the brightness of the blue screen is achieved by activating the blue sub-pixels as the auxiliary color sub-pixels.

Optionally, the display panel includes a plurality of pixel units, and each pixel unit includes a pixel.

The method further includes: controlling the driving current of the primary color sub-pixel of the pixel to be greater than the driving current of each auxiliary color sub-pixel.

When realizing the primary color display, the primary color sub-pixel is turned on, and other color sub-pixels are in the off state. To increase the brightness of the pixel, embodiments of the present disclosure can set other color sub-pixels as auxiliary color sub-pixels. When the primary color sub-pixel is turned on, the auxiliary color sub-pixels are also turned on. The partial light of the primary color sub-pixel and the light of the auxiliary color sub-pixel are mixed to form white light. On the basis of sacrificing partial NTSC color gamut saturation of the primary color sub-pixel, the brightness of the pixel is increased. Moreover, setting the driving current of the primary color sub-pixel to be greater than the driving current of each auxiliary color sub-pixel ensures that the brightness of the primary color sub-pixel is greater than that of each auxiliary color sub-pixel, thereby maintaining the pixel displaying the primary color.

Embodiments of the present disclosure set one sub-pixel of a plurality of color sub-pixels of a pixel as the primary color sub-pixel and the other sub-pixels as auxiliary color sub-pixels. The pixel still displays the primary color and ensures the NTSC color gamut saturation required by HUD technology. Furthermore, by synchronously activating the auxiliary color sub-pixels and the primary color sub-pixel, partial light of the primary color sub-pixel and light of the auxiliary color sub-pixel are mixed to form white light. This utilizes the white light to increase the brightness of the pixel, thereby improving the brightness of the display panel to meet the brightness requirements of HUD technology and enhancing the display effect of the display panel.

It should be noted that in the present disclosure, terms such as “first” and “second” are used merely to distinguish one entity or operation from another, and do not necessarily imply any actual relationship or order between these entities or operations. Moreover, the terms “comprise”, “include”, or any other variant thereof are intended to cover non-exclusive inclusion, such that processes, methods, items, or devices comprising a series of elements include not only those elements explicitly listed but also other elements not explicitly listed but inherent to such processes, methods, items, or devices. In the absence of further limitations, the elements defined by the statement “comprising a . . . ” do not exclude the presence of additional identical elements in the processes, methods, items, or devices comprising the elements.

The above are specific embodiments of the present disclosure, enabling those skilled in the art to understand or implement the present disclosure. Various modifications to these embodiments will be apparent to those persons of ordinary skill in the art, and the general principles defined herein may be implemented in other embodiments without departing from the spirit or scope of the present disclosure. Therefore, the present disclosure should not be limited to these embodiments described herein but should encompass the broadest scope consistent with the principles and novel features disclosed herein.

What is claimed is:

1. A display panel, comprising a plurality of pixels, wherein
a pixel of the plurality of pixels comprises a plurality of color sub-pixels; one color sub-pixel of the plurality of color sub-pixels of the pixel is a primary color sub-pixel, and other color sub-pixels are auxiliary color sub-pixels; and
when the primary color sub-pixel of the pixel is turned on, the auxiliary color sub-pixels of the pixel are turned on; the auxiliary color sub-pixels of the pixel and partial light of the primary color sub-pixel are mixed into white light; and the pixel displays a primary color.

2. The display panel according to claim 1, further comprising a plurality of pixel units, wherein a pixel unit of the plurality of pixel units comprises the plurality of pixels; and
primary color sub-pixels of a same pixel unit have different colors.

3. The display panel according to claim 2, wherein an area of the primary color sub-pixel is larger than an area of an auxiliary color sub-pixel in the pixel.

4. The display panel according to claim 2, wherein
the auxiliary color sub-pixels in the pixel comprises at least a first auxiliary color sub-pixel and a second auxiliary color sub-pixel;
an area of the first auxiliary color sub-pixel is larger than an area of the second auxiliary color sub-pixel; and
a human eye sensitivity to the first auxiliary color sub-pixel is greater than a human eye sensitivity to the second auxiliary color sub-pixel.

5. The display panel according to claim 2, wherein
the auxiliary color sub-pixels in the pixel comprises at least a third auxiliary color sub-pixel and a fourth auxiliary color sub-pixel; and
an area of the third auxiliary color sub-pixel is larger than an area of the fourth auxiliary color sub-pixel; and a luminous efficiency of the third auxiliary color sub-pixel is less than a luminous efficiency of the fourth auxiliary color sub-pixel.

6. The display panel according to claim 2, wherein the primary color sub-pixel and each auxiliary color sub-pixel in the pixel are connected to a same driving circuit.

7. The display panel according to claim 2, wherein the primary color sub-pixel and the auxiliary color sub-pixels in the pixel are connected to different driving circuits.

8. The display panel according to claim 7, wherein the primary color sub-pixel in the pixel is connected to a first driving circuit, and each auxiliary color sub-pixel in the same pixel is connected to a same second driving circuit.

9. The display panel according to claim 7, wherein the primary color sub-pixel and each auxiliary color sub-pixel in the pixel are connected to different driving circuits in a one-to-one correspondence.

10. The display panel according to claim 2, wherein the auxiliary color sub-pixels in the same pixel are located on different sides of the primary color sub-pixel.

11. The display panel according to claim 10, wherein the auxiliary color sub-pixels in the same pixel are located on opposite sides of the primary color sub-pixel.

12. The display panel according to claim 2, wherein the auxiliary color sub-pixels in the same pixel are located on a same side of the primary color sub-pixel.

13. The display panel according to claim 2, wherein primary color sub-pixels of a same color are arranged along a column direction; adjacent two rows of pixels share auxiliary color sub-pixels, and the shared auxiliary color sub-pixels are located between primary color sub-pixels of the adjacent two rows of pixels.

14. The display panel according to claim 2, wherein
the pixel unit comprises at least a first primary color sub-pixel and a second primary color sub-pixel;
the auxiliary color sub-pixels are located between primary color sub-pixels of adjacent two rows of pixels; a luminous efficiency of the first primary color sub-pixel is less than a luminous efficiency of the second primary color sub-pixel; and
first primary color sub-pixels in adjacent two rows of pixels share auxiliary color sub-pixels; second primary color sub-pixels in the adjacent two rows of pixels correspond to the auxiliary color sub-pixels, respectively; and an area of the shared auxiliary color sub-pixels is larger than an area of non-shared auxiliary color sub-pixels.

15. The display panel according to claim 2, wherein
primary color sub-pixels of a same color are arranged along a column direction; the auxiliary color sub-pixels are located between primary color sub-pixels of adjacent two rows of pixels; and
the pixel unit at least comprises a fifth auxiliary color sub-pixel and a sixth auxiliary color sub-pixel; a luminous efficiency of the fifth auxiliary color sub-pixel is less than a luminous efficiency of the sixth auxiliary color sub-pixel; the primary color sub-pixels of adjacent two rows of pixels share the fifth auxiliary color sub-pixel; the primary color sub-pixels in the adjacent two rows of pixels correspond to sixth auxiliary color sub-pixels, respectively; and an area of the fifth auxiliary color sub-pixel is larger than an area of the sixth auxiliary color sub-pixel.

16. The display panel according to claim 1, further comprising a plurality of pixel units; a pixel unit of the plurality of pixel units comprises the pixel; and a driving current of the primary color sub-pixel of the pixel is greater than a driving current of each auxiliary color sub-pixel.

17. The display panel according to claim 16, wherein
the auxiliary color sub-pixel in the pixel comprises at least a fifth auxiliary color sub-pixel and a sixth auxiliary color sub-pixel; and
a driving current of the fifth auxiliary color sub-pixel is greater than a driving current of the sixth auxiliary color sub-pixel; a human eye sensitivity to the fifth auxiliary color sub-pixel is greater than a human eye sensitivity to the sixth auxiliary color sub-pixel.

18. The display panel according to claim 16, wherein the auxiliary color sub-pixel in the pixel comprises at least a seventh auxiliary color sub-pixel and an eighth auxiliary color sub-pixel; and
a driving current of the seventh auxiliary color sub-pixel is greater than a driving current of the eighth auxiliary color sub-pixel; a luminous efficiency of the seventh auxiliary color sub-pixel is less than a luminous efficiency of the eighth auxiliary color sub-pixel.

19. The display panel according to claim 1, wherein the sub-pixel is a micro-light-emitting diode or an organic light-emitting diode.

20. A display apparatus, comprising:
a display panel, comprising a plurality of pixels, wherein
a pixel of the plurality of pixels comprises a plurality of color sub-pixels; one color sub-pixel of the plurality of color sub-pixels of the pixel is a primary color sub-pixel, and other color sub-pixels are auxiliary color sub-pixels;
when the primary color sub-pixel of the pixel is turned on, the auxiliary color sub-pixels of the pixel are turned on; the auxiliary color sub-pixels of the pixel and partial light of the primary color sub-pixel are mixed into white light; and the pixel displays a primary color.
